(19) United States
(12) Patent Application Publication
(10) Pub. No.: US 2013/0257453 A1
(43) Pub. Date: Oct. 3, 2013

(54) RF ESD Device Level Differential Voltage Measurement

(71) Applicant: Marcos HERNANDEZ, San Jose, CA (US)

(72) Inventor: Marcos HERNANDEZ, San Jose, CA (US)

(21) Appl. No.: 13/436,353

(22) Filed: Mar. 30, 2012

(51) Int. Cl. G01R 27/28

(52) U.S. Cl. 324/612

(57) ABSTRACT

A method of measuring, recording, and calculating high speed differential voltage measurements across a device-under-test during electrostatic discharge testing of for discrete devices and silicon wafer probing uses high frequency components and a combination of high impedance resistors and attenuators to allow differential voltage measurements of stress signals including IED 61000-4-2, HMM, HBM, and MM with voltages in excess of +/−12000V.

### BACKGROUND

Electrostatic discharge (ESD) is one of the biggest threats to semiconductor reliability. The semiconductor devices are tested against industry standards such as ESDA, JEDEC, AEC, and Military. The industry standards specify test voltages and current waveforms that an ESD simulator must comply with to ensure repeatability and consistency for electrostatic discharge robustness of a given semiconductor device or integrated circuit (IC). During Equipment qualification, the compliance standards include collecting a set of waveforms that contains the ESD voltages and current.

In recent years, it has become important to collect current information during device testing and not only during equipment simulation qualification. Collection of current waveform data while the device is under tests results in better ESD protection circuits that can be embedded into a semiconductor device. Current waveform data is measured using current probes, e.g. Tektronix CT1, CT2, and CT3, The current probes introduce few changes to the current waveforms and thus have a minimum impact in simulator performance.

One prior art technique for gathering voltage date is direct voltage probe measurement using an off the shelf voltage probe, e.g. Tektronix P2220 and P2221. The measurement accuracy has two major problems. First, the maximum bandwidth of the probe is <200 MHz and thus, the maximum voltage that can be measured is 300V (30V RMS). Second, the probe itself presents a capacitance of 17 pF which affects the waveform produced by an ESD simulator (specifications for 10× position).

Another prior art technique uses a voltage probe and a voltage divider, shown in FIG. 1. This circuit achieves higher voltage measurement capabilities (VR2 Vin (R2/(R1 R2)) than the direct voltage probe method, but has bandwidth limitations due to the voltage probe and the resistor network used. An additional drawback is that it is impractical to change the dynamic range of the measurement.

Both of the aforementioned techniques are impractical to use close to the device under test (DUT) because of their physical size making the measurement away from the device under test (remote), shown in FIG. 2. The circuit impedance is very important for ESD testing and to make measurements that are meaningful for both current and voltage, they have to be performed as close to the device under test as possible.

Voltage waveform collection is more challenging. The voltages used for ESD are typically in the thousands of volts and can exceed +/−8000V. A voltage probe introduces parasitic into the simulator circuit that alters the characteristics of the waveform produced. The frequency required to collect the waveform is above 500 MHz.

### SUMMARY

A method of measuring, recording, and calculating high speed differential voltage measurements across a device-under-test during electrostatic discharge testing of discrete devices and silicon wafer probing uses high frequency components and a combination of high impedance resistors and attenuators to allow differential voltage measurements of stress signals including IED 610004-2, Human Metal Model (HMM), Human Body Model (HBM), and Machine Model (MM) with voltages in excess of +/−12000V.

### BRIEF DESCRIPTION OF THE DRAWINGS

FIG. 1 illustrates a prior art system.

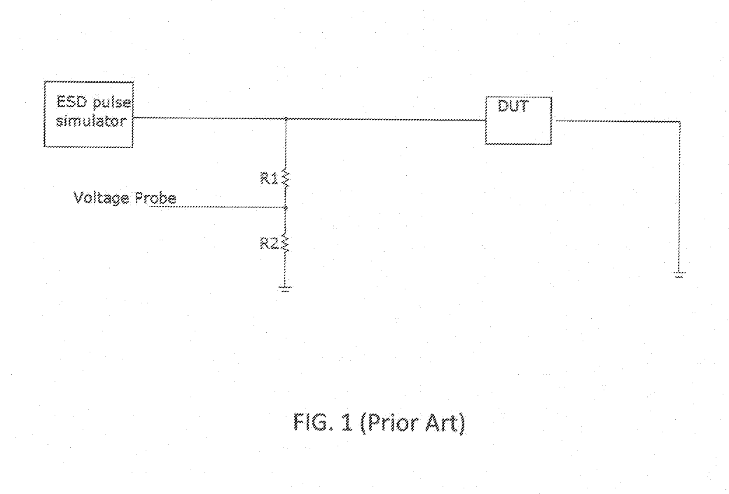

FIG. 2 illustrates a prior art system.

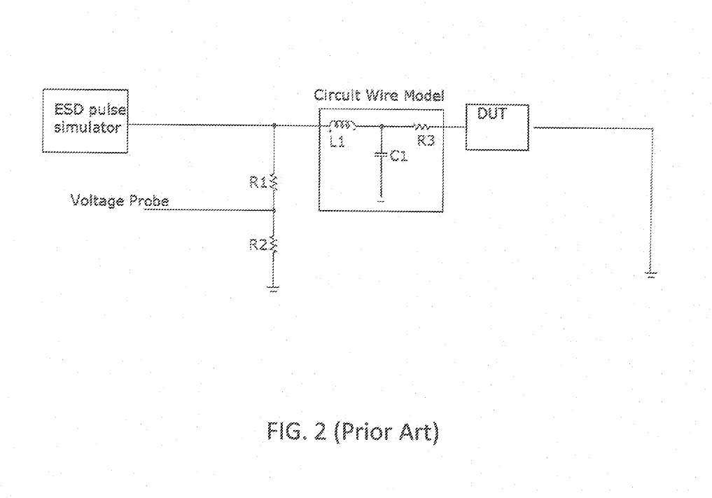

FIG. 3 illustrates a functional block diagram of a tester according to the invention.

FIG. 4 illustrates a process flowchart according to the invention.

### DETAILED DESCRIPTION

The apparatus collects very high voltage, high frequency waveforms with little impact to the electrical characteristics of the simulator circuit to therefore preserve the waveforms to industry standards.

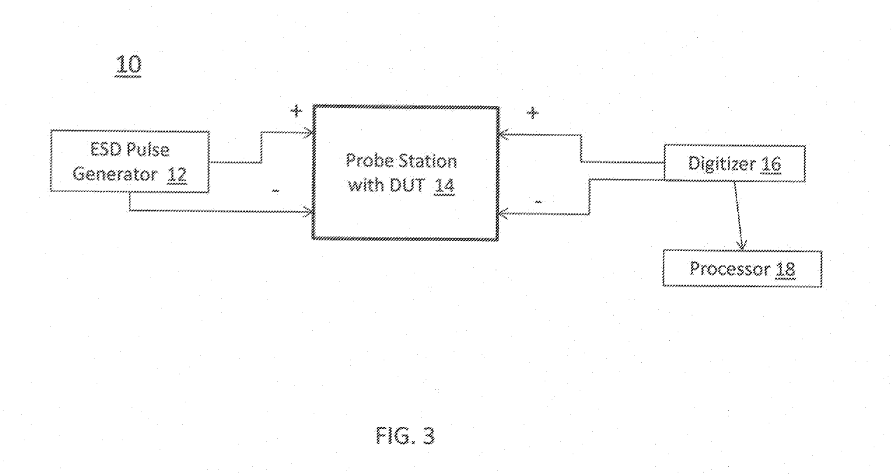

FIG. 3 illustrates a functional block diagram of a tester 10 according to the invention. A tester 10 includes an electro-static discharge (ESD) pulse generator 12, a probe station, 14, a high-speed digitizer 16, e.g. an oscilloscope, and a processor 18. The ESD pulse generator 12 and high speed digitizer 16 are differentially connected to the probe station 14. The probe station 14 supports the device-under-test DUT.

In operation, the voltage measurement is taken using a differential probe placed across the device-under test (DUT) to ensure an accurate measurement. The probe is high impedance, e.g. greater than 2500 Ohms, while the typical DUT ESD protection structures have a resistance of less than 5 Ohms. The high voltage waveform is collected using high frequency coaxial probes and 50 Ohm coaxial lines to interface with a high frequency digitizer, e.g. an oscilloscope. The use of 50 Ohm coaxial lines and needles provide the ability to use 50 Ohm attenuators readily available in industry, and providing high attenuation with low insertion loss and thus allowing voltage measurements in the thousands of volts.

The current and voltage probes are separated and this thereby eliminates the impedance contribution of the wiring and contact resistances. Only the voltage dropped across the DUT and not the attached coaxial probes are measured. The calculated resistance indicates the DUT's resistance alone.

As the digitizer probes carry miniscule current, the resistance of the probes does not add to the measurement. Thus, the cable lengths of the probes connecting the oscilloscope across the DUT will drop insignificant amounts of voltage, resulting in a voltage waveform that is very nearly the same as if it were connected directly across the DUT's resistance.

Any voltage dropped across the main current-carrying cables of the ESD pulse generator will not be measured by the digitizer and does not factor into the resistance calculation at all.

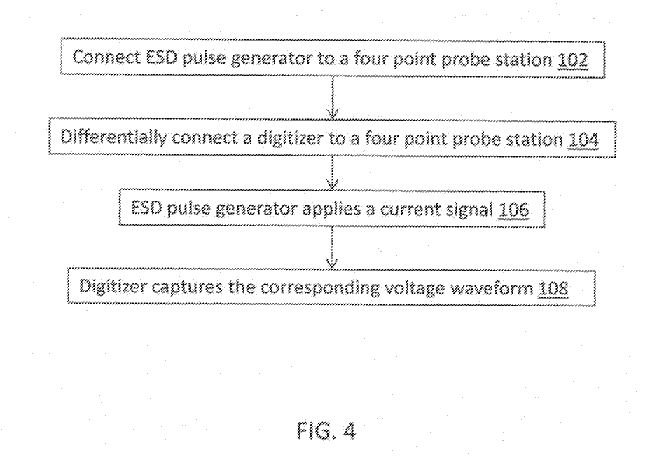

FIG. 4 illustrates a process flowchart according to the invention. In step 102 an ESD pulse generator is differentially connected to a four point probe station including the device under test. In step 104, a high speed digitizer with optional processor is differentially connected to the four point probe station. in step 106, the ESD pulse generator applies a current signal. In step 108, the high speed digitizer captures the corresponding voltage waveform.

1. A testing assembly for a device-under-test comprising:
an electro-static discharge (ESD) pulse generator;
a high-speed digitizer, generating voltage waveforms; and
four point probing station, differentially connected to the ESD pulse generator and the high speed digitizer, supporting the device-under-test.

2. A testing assembly, as in claim 1, the high speed digitizer being an oscilloscope.

3. A testing assembly, as in claim 1, a processor receiving the voltage waveforms and what do you with this?

4. A testing method comprising:
connecting an electro-static discharge pulse generator differentially across a device under test;
connecting a digitizer differentially across the device under test;
applying the electro-static discharge pulse generator; and
measuring a corresponding voltage waveform.

5. A testing method, as in claim 4, wherein the digitizer is an oscilloscope.
